(19) United States
(12) Patent Application Publication
(10) Pub. No.: US 2025/0192129 A1
(43) Pub. Date: Jun. 12, 2025

(54) SEMICONDUCTOR PACKAGE INCLUDING A COMPOSITE SPACER

(71) Applicant: SAMSUNG ELECTRONICS CO., LTD., SUWON-SI (KR)

(72) Inventors: Seunghyun BAIK, Suwon-si (KR); Yeji KWON, Suwon-si (KR)

(21) Appl. No.: 18/973,925

(22) Filed: Dec. 9, 2024

(30) Foreign Application Priority Data
Dec. 11, 2023 (KR) 10-2023-0178750

(51) Int. Cl. H01L 25/18; H01L 23/00; H01L 23/31; H01L 23/498; H10B 80/00

(52) U.S. Cl. CPC H01L 25/18; H01L 23/3121; H01L 23/49816; H01L 23/562; H01L 24/16; H01L 24/32; H01L 24/48; H01L 24/73; H10B 80/00; H01L 2224/16227; H01L 2224/32145; H01L 2224/32225; H01L 2224/48145; H01L 2224/48227; H01L 2224/73265; H01L 2225/0651; H01L 2225/06517; H01L 2924/1431; H01L 2924/1436; H01L 2924/1438

(57) ABSTRACT

A semiconductor package includes: a base substrate; a first spacer disposed on the base substrate; a composite spacer disposed on the base substrate and laterally spaced apart from the first spacer; a plurality of first semiconductor chips stacked on the composite spacer; and a plurality of second semiconductor chips stacked on the first spacer, wherein a portion of the composite spacer includes a first device region, wherein a remaining portion of the composite spacer includes a buffer region, wherein the first device region includes a semiconductor device, wherein the buffer region does not comprise a semiconductor device, and the first spacer does not comprise a semiconductor device.

### CROSS-REFERENCE TO RELATED APPLICATION

This application claims priority under 35 U.S.C. § 119 to Korean Patent Application No. 10-2023-0178750, filed on Dec. 11, 2023, in the Korean Intellectual Property Office, the disclosure of which is incorporated by reference herein in its entirety.

### TECHNICAL FIELD

Embodiments of the present inventive concept relate to a semiconductor package, and more particularly, to a semiconductor package including a composite spacer.

### DISCUSSION OF THE RELATED ART

With the recent trend of reducing the sizes and weights of electronic components and devices, it is desirable to shrink semiconductor packages that are mounted in the electronic components or devices. Although semiconductor packages have finite areas, the sizes and numbers of devices arranged in packages have been increasing. Therefore, it is desirable to efficiently arrange devices in finite areas of semiconductor packages.

### SUMMARY

According to an embodiment of the present inventive concept, a semiconductor package includes: a base substrate; a first spacer disposed on the base substrate; a composite spacer disposed on the base substrate and laterally spaced apart from the first spacer; a plurality of first semiconductor chips stacked on the composite spacer; and a plurality of second semiconductor chips stacked on the first spacer, wherein a portion of the composite spacer includes a first device region, wherein a remaining portion of the composite spacer includes a buffer region, wherein the first device region includes a semiconductor device, wherein the buffer region does not comprise a semiconductor device, and the first spacer does not comprise a semiconductor device.

According to an embodiment of the present inventive concept, a semiconductor package includes: a base substrate; a composite spacer disposed on the base substrate; a plurality of first semiconductor chips stacked on the composite spacer; and a plurality of second semiconductor chips stacked on the composite spacer and laterally spaced apart from the plurality of first semiconductor chips, wherein a portion of the composite spacer includes a first device region, wherein a remaining portion of the composite spacer includes a buffer region, wherein the first device region includes a semiconductor device, and the buffer region does not comprise a semiconductor device.

According to an embodiment of the present inventive concept, a semiconductor package includes: a base substrate; a first spacer disposed on the base substrate; a composite spacer disposed on the base substrate and laterally spaced apart from the first spacer; a plurality of first semiconductor chips stacked on the composite spacer; a plurality of second semiconductor chips stacked on the first spacer; connection terminals and dummy terminals, which are disposed between the composite spacer and the base substrate; and a plurality of third semiconductor chips stacked on the plurality of first semiconductor chips and the plurality of second semiconductor chips, wherein a portion of the composite spacer includes a first device region, wherein a remaining portion of the composite spacer includes a buffer region, wherein the first device region includes a semiconductor device, wherein the buffer region does not comprise a semiconductor device, wherein the first spacer does not comprise a semiconductor device, wherein the buffer region at least partially surrounds the first device region, wherein the connection terminals are arranged on the first device region and electrically connect the first device region to the base substrate, wherein the dummy terminals are arranged on the buffer region, wherein a planar shape of the composite spacer is substantially same as a planar shape of a lowermost first semiconductor chip from among the plurality of first semiconductor chips, wherein an outer border of the lowermost first semiconductor chip is substantially aligned with an outer border of the composite spacer, wherein a planar shape of the first spacer is substantially same as a planar shape of a lowermost second semiconductor chip from among the plurality of second semiconductor chips, wherein an outer border of the lowermost second semiconductor chip is substantially aligned with an outer border of the first spacer, wherein the plurality of first semiconductor chips have same planar shapes as one another, wherein respective outer borders of the plurality of first semiconductor chips are substantially aligned with each other, wherein the plurality of second semiconductor chips have same planar shapes as one another, and respective outer borders of the plurality of second semiconductor chips are substantially aligned with each other.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view of a semiconductor package according to an embodiment of the present inventive concept;

FIG. 2 is a cross-sectional view of the semiconductor package of FIG. 1, taken along line A-A′ of FIG. 1;

FIG. 3 is a plan view illustrating a method of fabricating a composite spacer that is included in a semiconductor package, according to an embodiment of the present inventive concept;

FIG. 4 is a cross-sectional view of a semiconductor package according to an embodiment of the present inventive concept;

FIG. 5 is a cross-sectional view of the semiconductor package of FIG. 4, taken along line B-B′ of FIG. 4 of the present inventive concept;

FIG. 6 is a plan view illustrating a method of fabricating a composite spacer that is included in a semiconductor package, according to an embodiment of the present inventive concept;

FIG. 7 is a cross-sectional view of a semiconductor package according to an embodiment of the present inventive concept;

FIG. 8 is a cross-sectional view of a semiconductor package according to an embodiment of the present inventive concept;

FIG. 9 is a cross-sectional view of the semiconductor package of FIG. 8, taken along line C-C′ of FIG. 8;

FIG. 10 is a cross-sectional view of a semiconductor package according to an embodiment of the present inventive concept;

FIG. 11 is a cross-sectional view of the semiconductor package of FIG. 10, taken along line D-D′ of FIG. 10;

FIG. 12 is a cross-sectional view of a semiconductor package according to an embodiment of the present inventive concept; and

FIG. 13 is a cross-sectional view of the semiconductor package of FIG. 12, taken along line E-E′ of FIG. 12.

### DETAILED DESCRIPTION OF THE EMBODIMENTS

Hereinafter, embodiments of the present inventive concept will be described in detail with reference to the accompanying drawings.

It should be understood that the following embodiments of the present inventive concept may be embodied in different ways and the scope of the present inventive concept is not limited to the following embodiments. In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

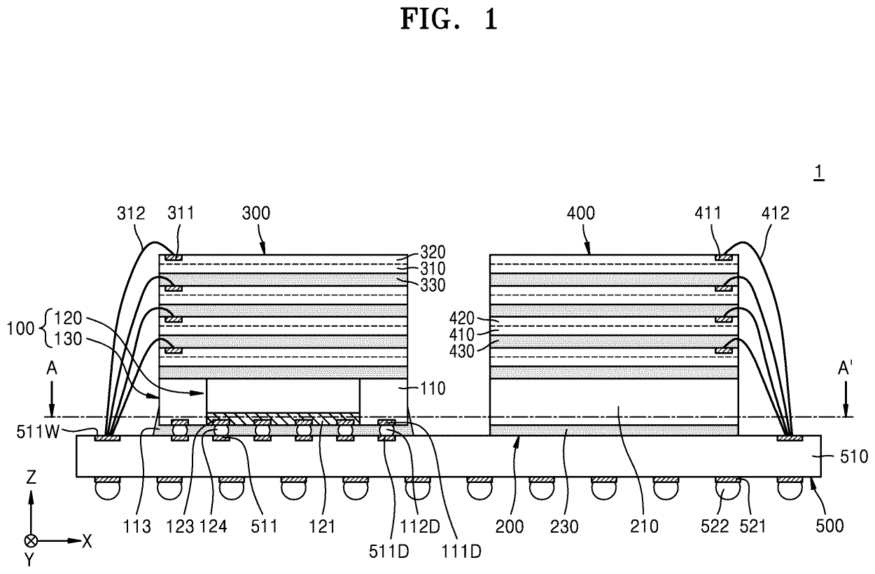

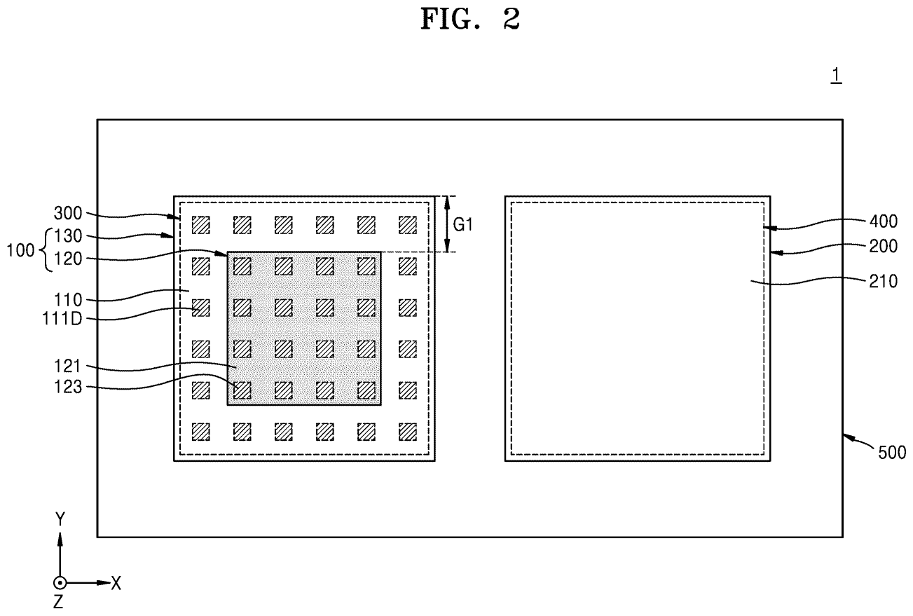

FIG. 1 is a cross-sectional view of a semiconductor package 1 according to an embodiment of the present inventive concept. FIG. 2 is a cross-sectional view of the semiconductor package 1, taken along line A-A′ of FIG. 1.

Herein, a first direction refers to an X direction, and a second direction refers to a Y direction. The first direction and the second direction may be perpendicular to each other. A third direction refers to a Z direction and may be perpendicular to each of the first direction and the second direction. A horizontal plane or a plane refers to an X-Y plane. The upper surface of a specific object refers to a surface located in a positive third direction based on the specific object, and the lower surface of the specific object refers to a surface located in a negative third direction based on the specific object.

Referring to FIGS. 1 and 2, the semiconductor package 1 according to an embodiment of the present inventive concept may include a base substrate 510, a composite spacer 100, a first spacer 200, a plurality of first semiconductor chips 300 that are stacked on each other, and a plurality of second semiconductor chips 400 that are stacked on each other.

The composite spacer 100 may be arranged on the base substrate 510. The composite spacer 100 may include a first device region 120. A remaining region except for the first device region 120 in the composite spacer 100 may be referred to as a buffer region 130.

A first semiconductor device 121 may be arranged in a portion of a composite spacer substrate 110, and a region of the composite spacer substrate 110, which includes a region including the first semiconductor device 121 and extends from the first semiconductor device 121 to the upper surface of the composite spacer substrate 110, may be referred to as the first device region 120. For example, the first semiconductor device 121 may be disposed in a portion of the first device region 120. Unlike the first device region 120, the buffer region 130 does not include devices, such as the first semiconductor device 121 that is included in the first device region 120. The first device region 120 and the buffer region 130 are formed as one body in one composite spacer substrate 110. The first device region 120 and the buffer region 130 may be divided based on whether the first semiconductor device 121 is included therein or not.

The buffer region 130 corresponds to a region in which the first device region 120 is not formed, and the composite spacer 100 may be fabricated not to expose the outer border of the first device region 120 to the outside of the composite spacer 100 such that wafer cutting is not performed with an intrusion into the first device region 120 during the process of fabricating the composite spacer 100. For example, as shown in FIG. 2, all side surfaces of the first device region 120 may be surrounded by the buffer region 130. In addition, during the process of fabricating the composite spacer 100 by cutting a wafer, there is a need to reduce the possibility of cutting the first device region 120 and also reduce the possibility of damaging the first device region 120 due to a crack generated by cutting. Therefore, the buffer region 130 surrounding the first device region 120 may have a certain thickness or more.

As shown in FIG. 2, the outer border of the first device region 120 may be separated from the outer border of the buffer region 130, that is, the outer border of the composite spacer 100, by as much as a first width G1. That is, the thickness with which the buffer region 130 surrounds the first device region 120 may be the first width G1. The first width G1 may be, for example, about 50 μm or more.

The first semiconductor device 121 may be arranged in a portion of the composite spacer substrate 110 to be adjacent to a surface of the composite spacer substrate 110, which faces the base substrate 510. The first device region 120 may include a logic semiconductor chip having circuits for controlling a memory device, for example, a dynamic random-access memory (DRAM) device or a flash memory device. The first device region 120 may function as a controller chip. For example, the first device region 120 may include a logic semiconductor chip having circuits for controlling the plurality of first semiconductor chips 300 arranged on the composite spacer 100 and the plurality of second semiconductor chips 400 arranged on the first spacer 200.

The first device region 120 may include a plurality of individual devices of various kinds. For example, the first device region 120 may include a metal-oxide-semiconductor field effect transistor (MOSFET), such as a complementary metal-insulator-semiconductor (CMOS) transistor, a system large-scale integration (LSI), an active element, a passive element, and the like.

First connection pads 123 and first dummy pads 111D may be arranged on the lower surface of the composite spacer 100. The first connection pads 123 may be arranged on the lower surface of the first device region 120, and the first dummy pads 111D may be arranged on the lower surface of the buffer region 130. For example, the first connection pads 123 may be arranged on the lower surface of the composite spacer 100 and between the first device region 120 and the base substrate 510, and the first dummy pads 111D may be arranged on the lower surface of the composite spacer 100 and between the buffer region 130 and the base substrate 510. The composite spacer 100 may be arranged on the base substrate 510 in a flip-chip manner.

The first connection pads 123 may be electrically connected to the first semiconductor device 121 of the first device region 120, and the first dummy pads 111D might not be electrically connected to any semiconductor devices including the first semiconductor device 121.

Base bonding pads 511W, second connection pads 511, and second dummy pads 511D may be arranged on the upper surface of the base substrate 510. External connection pads 521 may be arranged on the lower surface of the base substrate 510. The base bonding pads 511W, the second connection pads 511, and the external connection pads 521 may be electrically connected to each other via wiring lines that are arranged in the base substrate 510. External connection terminals 522 may be respectively arranged on the external connection pads 521. The second dummy pads 511D may be connected to the first dummy pads 111D via dummy connection terminals 112D, respectively. However, the second dummy pads 511D, the first dummy pads 111D, and the dummy connection terminals 112D might not be electrically connected to any other components except for each other.

Connection terminals 124 may be arranged, respectively, between the first connection pads 123 that are on the lower surface of the composite spacer 100 and the second connection pads 511 that are on the upper surface of the base substrate 510. The first connection pads 123 may be electrically connected to the second connection pads 511 via the connection terminals 124, respectively. The connection terminals 124 may each include, but are not limited to, a bump, a ball, or a combination thereof.

A first underfill layer 113 may be arranged between the lower surface of the composite spacer 100 and the upper surface of the base substrate 510. The first underfill layer 113 may at least partially surround the side surfaces of the connection terminals 124. The first underfill layer 113 may include a resin. For example, the first underfill layer 113 may be formed of an epoxy resin by a capillary underfill method. A filler may be mixed in the first underfill layer 113 and may include, for example, silica.

The plurality of first semiconductor chips 300 may be sequentially stacked and arranged on the composite spacer 100. The plurality of first semiconductor chips 300 may be stacked to overlap each other in the vertical direction. The plurality of first semiconductor chips 300 may each have the same shape as each other in a plan view. For example, the planar shape of each of the plurality of first semiconductor chips 300 may be substantially the same as the planar shape of the composite spacer 100. The respective outer borders of the plurality of first semiconductor chips 300 may be substantially aligned with each other in the vertical direction. For example, the outer border of the planar shape of each of the plurality of first semiconductor chips 300 may be substantially aligned with the outer border of the planar shape of the composite spacer 100 in the vertical direction. Each of the plurality of first semiconductor chips 300 may have a face-up arrangement such that an active surface of each of the first semiconductor substrate 310 faces upwards.

As shown in FIG. 2, the outer border of the planar shape of each of the plurality of first semiconductor chips 300 as indicated by a dashed line may be substantially consistent with the outer border of the planar shape of the composite spacer 100. In FIG. 2, the outer border of the planar shape of each of the plurality of first semiconductor chips 300 and the outer border of the planar shape of the composite spacer 100 are illustrated with a slight size difference therebetween for distinction; however, the present inventive concept is not limited thereto.

Each of the plurality of first semiconductor chips 300 may include a first semiconductor device 320. The first semiconductor device 320 may include, for example, a memory device. For example, the first semiconductor device 320 may include DRAM or flash memory.

Each of the plurality of first semiconductor chips 300 may include the first semiconductor substrate 310 having an active surface, on which the first semiconductor device 320 is formed, and a plurality of first chip pads 311 arranged on the upper surface of each of the plurality of first semiconductor chips 300. The plurality of first chip pads 311 may correspond to edge pads arranged adjacent to the edge of the upper surface of the first semiconductor chip 300. Some of the plurality of first chip pads 311, which are included in each of the plurality of first semiconductor chips 300, may correspond to data pads for the transmission of data signals.

Each of the plurality of first semiconductor chips 300 may have a first die-attach film 330 attached on the lower surface thereof and may be attached onto a structure thereunder. For example, the lowermost first semiconductor chip 300 from among the plurality of first semiconductor chips 300 may have a first die-attach film 330 disposed between the lowermost first semiconductor chip 300 and the composite spacer 100. The first die-attach film 330 of the lowermost first semiconductor chip 300 may be attached onto the composite spacer 100. For the remaining first semiconductor chips 300 from among the plurality of first semiconductor chips 300, each first die-attach film 330 may be arranged between the remaining first semiconductor chips 300. For example, the first die-attach film 330 may have substantially the same horizontal width and horizontal area as those of the first semiconductor chip 300 that is attached onto the upper surface of the first die-attach film 330. Therefore, the outer border of the first die-attach film 330 may be substantially aligned in the vertical direction with the outer border of the first semiconductor substrate 310 arranged on the upper surface of the first die-attach film 330.

The first die-attach film 330 may cover the plurality of first chip pads 311 of the first semiconductor chip 300 placed under the first die-attach film 330. For example, a first chip pad 311 that is disposed on an uppermost first semiconductor device 320 of the plurality of first semiconductor devices 320 might not be covered by the first die-attach film 330. A portion of one end of each of a plurality of first bonding wires 312 respectively connected to the plurality of first chip pads 311 may be buried in the first die-attach film 330. The first die-attach film 330 may include, for example, an inorganic adhesive or a polymeric adhesive. The polymeric adhesive may include, for example, a thermosetting polymer or a thermoplastic polymer. In the case of the thermosetting polymer, monomers thereof have a three-dimensional cross-linking structure after being molded by heating and are not softened even when reheated. In addition, the thermoplastic polymer is a resin exhibiting plasticity by heating and has a linear polymeric structure. In addition, the polymeric adhesive may include a hybrid-type polymeric adhesive made by mixing the above two components, that is, the thermosetting polymer and the thermoplastic polymer.

One end of each of the plurality of first bonding wires 312 may be attached to each of the plurality of first chip pads 311 of the plurality of first semiconductor chips 300, and the other end of each of the plurality of first bonding wires 312 may be attached to each of a plurality of base bonding pads 511W.

The first spacer 200 may include a spacer substrate 210 and a spacer adhesive film 230. The spacer substrate 210 may arranged to be attached onto the upper surface of the base substrate 510 by the spacer adhesive film 230 that is disposed on the lower surface of the spacer substrate 210. The first spacer 200 may include a dummy chip. The first spacer 200 might not include a semiconductor device, unlike the composite spacer 100. For example, the spacer adhesive film 230 may have substantially the same horizontal width and horizontal area as those of the spacer substrate 210 that is attached onto the upper surface of the spacer adhesive film 230. Therefore, the outer border of the spacer adhesive film 230 may be substantially aligned in the vertical direction with the outer border of the spacer substrate 210 that is attached onto the upper surface of the spacer adhesive film 230. The thickness of the first spacer 200 in the vertical direction may be substantially equal to the thickness of the composite spacer 100 in the vertical direction.

The plurality of second semiconductor chips 400 may be sequentially stacked and arranged on the first spacer 200. The plurality of second semiconductor chips 400 may be stacked to overlap each other in the vertical direction. The plurality of second semiconductor chips 400 may each have the same shape in a plan view. The planar shape of each of the plurality of second semiconductor chips 400 may be substantially the same as the planar shape of the first spacer 200. The respective outer borders of the plurality of second semiconductor chips 400 may be substantially aligned with each other in the vertical direction. The outer border of the planar shape of each of the plurality of second semiconductor chips 400 may be substantially aligned with the outer border of the planar shape of the first spacer 200 in the vertical direction. Each of the plurality of second semiconductor chips 400 may have a face-up arrangement such that an active surface of a second semiconductor substrate 410 faces upwards.

As shown in FIG. 2, the outer border of the planar shape of each of the plurality of second semiconductor chips 400 as indicated by a dashed line may be substantially consistent with the outer border of the planar shape of the first spacer 200. In FIG. 2, the outer border of the planar shape of each of the plurality of second semiconductor chips 400 and the outer border of the planar shape of the first spacer 200 are illustrated with a slight size difference therebetween for distinction; however, the present inventive concept is not limited thereto.

Each of the plurality of second semiconductor chips 400 may include a second semiconductor device 420. The second semiconductor device 420 may include, for example, a memory device. For example, the second semiconductor device 420 may include DRAM or flash memory.

Each of the plurality of second semiconductor chips 400 may include the second semiconductor substrate 410 having an active surface, on which the second semiconductor device 420 is formed, and a plurality of second chip pads 411 arranged on the upper surface of each of the each of the plurality of second semiconductor chips 400. The plurality of second chip pads 411 may correspond to edge pads that are arranged adjacent to the edge of the upper surface of the second semiconductor chip 400. Some of the plurality of second chip pads 411, which are included in each of the plurality of second semiconductor chips 400, may correspond to data pads for the transmission of data signals.

The lowermost second semiconductor chip 400 from among the plurality of second semiconductor chips 400 may have a second die-attach film 430 disposed between the lowermost second semiconductor chip 400 and the first spacer 200. The second die-attach film 430 of the lowermost second semiconductor chip 400 may be attached onto the first spacer 200. For the remaining second semiconductor chips 400 from among the plurality of second semiconductor chips 400, each second die-attach film 430 may be arranged between the remaining second semiconductor chips 400. The second die-attach film 430 may have substantially the same horizontal width and horizontal area as those of the second semiconductor chip 400 that is attached onto the upper surface of the second die-attach film 430. Therefore, the outer border of the second die-attach film 430 may be substantially aligned in the vertical direction with the outer border of the second semiconductor substrate 410 that is arranged on the upper surface of the second die-attach film 430.

The second die-attach film 430 may cover the plurality of second chip pads 411 of the second semiconductor chip 400 placed under the second die-attach film 430. For example, a second chip pad 411 of an uppermost second semiconductor chip 400 of the plurality of second semiconductor chips 400 might not be covered by the second die-attach film 430. A portion of one end of each of a plurality of second bonding wires 412 respectively connected to the plurality of second chip pads 411 may be buried in the second die-attach film 430. The second die-attach film 430 may include, for example, an inorganic adhesive or a polymeric adhesive.

One end of each of the plurality of second bonding wires 412 may be attached to each of the plurality of second chip pads 411 in the plurality of second semiconductor chips 400, and the other end of each of the plurality of second bonding wires 412 may be attached to each of the plurality of base bonding pads 511W.

Unlike the semiconductor package 1 according to an embodiment of the present inventive concept, in general semiconductor packages, a spacer and a controller chip may be arranged between stacked semiconductor chips and a base substrate. The spacer and the controller chip may support one stack of semiconductor chips. Each of the spacer and the controller chip may be separately fabricated and may be separately arranged on the base substrate.

In the semiconductor package 1 according to an embodiment of the present inventive concept, the composite spacer 100 that includes the first device region 120 functioning as a controller chip is arranged between the base substrate 510 and the plurality of first semiconductor chips 300 that are stacked on each other. By doing this, unlike the general case of separately arranging a spacer and a controller chip, because the composite spacer 100, in which a spacer and a controller are integrated, is fabricated, the productivity of the semiconductor package 1 may increase. In addition, because the integrated composite spacer 100 is fabricated by using a silicon substrate, the stiffness of the semiconductor package 1 may increase unlike a general semiconductor package in which a spacer and a controller are separately arranged. Furthermore, because the integrated composite spacer 100 may reduce or prevent the warpage of the semiconductor package 1 during the fabrication and operation of the semiconductor package 1, the composite spacer 100 may increase the mechanical properties of the semiconductor package 1.

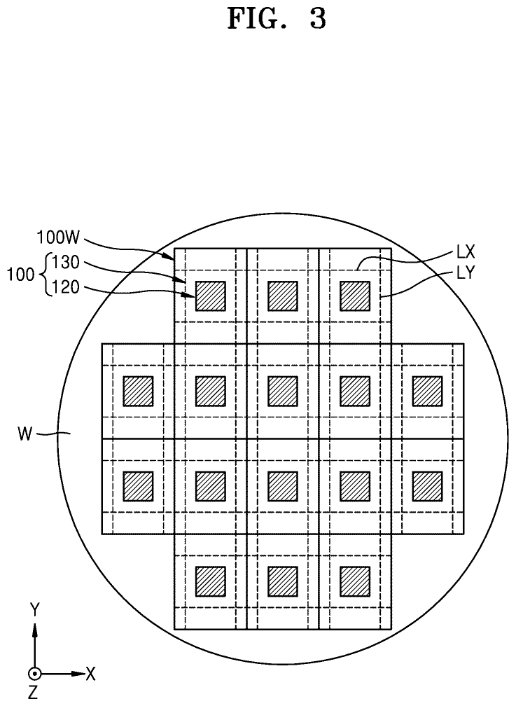

FIG. 3 is a plan view illustrating a method of fabricating the composite spacer 100 that is included in the semiconductor package 1, according to an embodiment of the present inventive concept.

Referring to FIG. 3, a plurality of preliminary composite spacers 100W including the first device region 120 may be formed on a wafer W. Cutting along each first line LX and each second line LY may be performed on the wafer W, thereby forming the composite spacer 100. For example, the size and shape of the composite spacer 100 may be determined depending on positions at which the first line LX and the second line LY are set. However, in setting each of the first line LX and the second line LY, each of the first line LX and the second line LY may be set to be separated from the first device region 120 by a specific interval or more, and the first width G1 described with reference to FIG. 2 may correspond to the specific interval. In addition, unlike in FIG. 3, the preliminary composite spacer 100W may be formed with substantially the same size as the size of the composite spacer 100, thereby fabricating a larger number of composite spacers 100 from the wafer W.

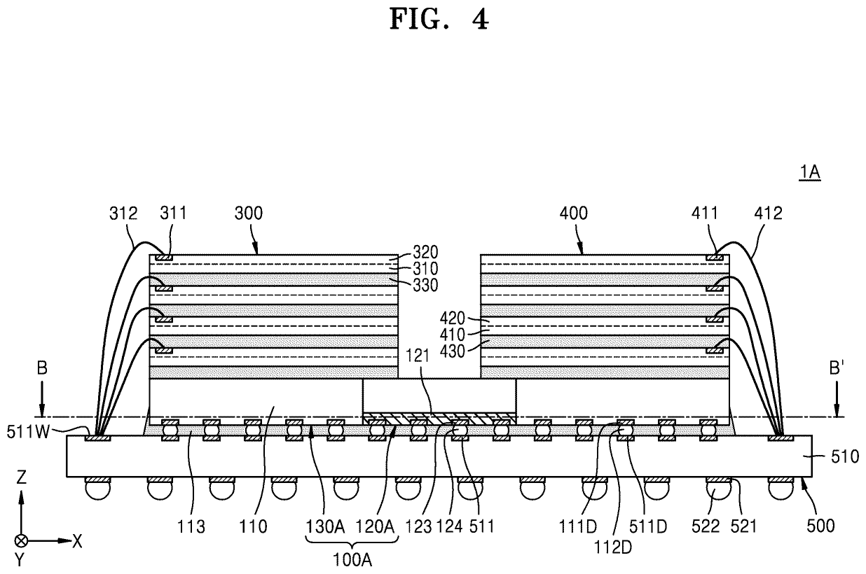

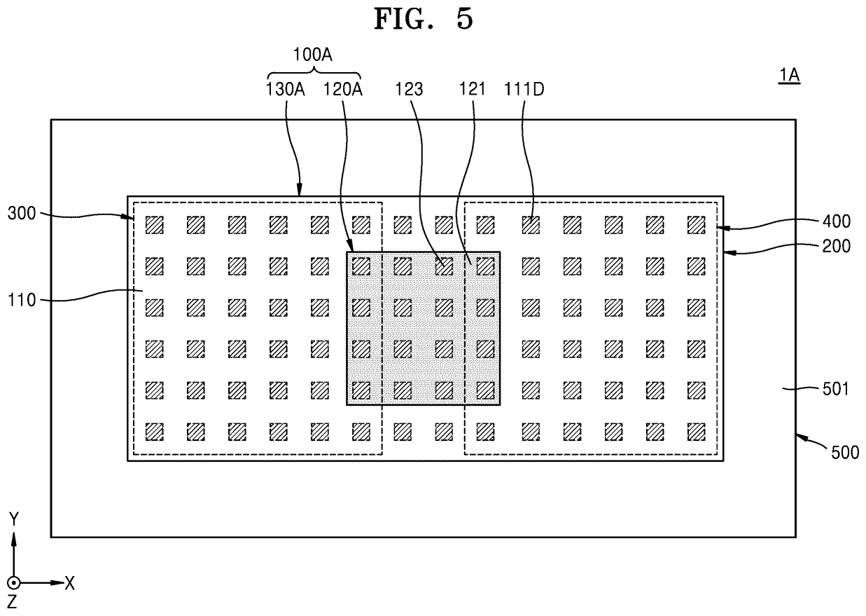

FIG. 4 is a cross-sectional view of a semiconductor package 1A according to an embodiment of the present inventive concept. FIG. 5 is a cross-sectional view of the semiconductor package 1A, taken along the line B-B′ of FIG. 4.

Referring to FIGS. 4 and 5, the semiconductor package 1A according to an embodiment of the present inventive concept may include a base substrate 510, a composite spacer 100A, a plurality of first semiconductor chips 300 that are stacked on each other, and a plurality of second semiconductor chips 400 that are stacked on each other.

The composite spacer 100A may be arranged on the base substrate 510. The composite spacer 100A may include a first device region 120A. A remaining region except for the first device region 120 in the composite spacer 100A may be referred to as a buffer region 130A.

A first semiconductor device 121 may be arranged in a portion of the composite spacer substrate 110, and a region, which includes a region including the first semiconductor device 121 and extends from the first semiconductor device 121 to the upper surface of the composite spacer substrate 110, may be referred to as the first device region 120A. Unlike the first device region 120A, the buffer region 130A does not include devices, such as the first semiconductor device 121 that is included in the first device region 120A. The first device region 120A and the buffer region 130A are formed as one body in one composite spacer substrate 110. The first device region 120A and the buffer region 130A may be divided based on whether the first semiconductor device 121 is included therein or not. For example, the first device region 120A may be located in a central portion of the composite spacer substrate 110.

The first semiconductor device 121 may be arranged in a portion of the composite spacer substrate 110 to be adjacent to a surface of the composite spacer substrate 110, which faces the base substrate 510. The first device region 120A may include a logic semiconductor chip having circuits for controlling a memory device, for example, a DRAM device or a flash memory device. The first device region 120A may function as a controller chip. For example, the first device region 120A may include a logic semiconductor chip having circuits for controlling the plurality of first semiconductor chips 300 stacked and arranged on the composite spacer 100A and the plurality of second semiconductor chips 400 stacked and arranged on the composite spacer 100A.

First connection pads 123 and first dummy pads 111D may be arranged on the lower surface of the composite spacer 100A. The first connection pads 123 may be arranged on the lower surface of the first device region 120A, and the first dummy pads 111D may be arranged on the lower surface of the buffer region 130A. For example, the first connection pads 123 may be arranged on the lower surface of the composite spacer 100A and between the first device region 120A and the base substrate 510, and the first dummy pads 111D may be arranged on the lower surface of the composite spacer 100A and between the buffer region 130A and the base substrate 510. Therefore, the composite spacer 100A may be arranged on the base substrate 510 in a flip-chip manner.

The plurality of first semiconductor chips 300 may be sequentially stacked on each other and arranged on the composite spacer 100A, and the plurality of second semiconductor chips 400 may also be sequentially stacked on each other and arranged on the composite spacer 100A. The plurality of first semiconductor chips 300 may be stacked to overlap each other in the vertical direction. The plurality of first semiconductor chips 300 may each have the same shape as each other in a plan view. The plurality of second semiconductor chips 400 may be stacked to overlap each other in the vertical direction. The plurality of second semiconductor chips 400 may each have the same shape as each other in a plan view.

A portion of the outer border of the planar shape of the lowermost first semiconductor chip 300 from among the plurality of first semiconductor chips 300 may be substantially aligned with a portion of the outer border of the planar shape of the composite spacer 100A. For example, as shown in FIG. 5, portions of the outer border of the planar shape of the lowermost first semiconductor chip 300 except for a portion of the outer border of the planar shape of the lowermost first semiconductor chip 300, which faces the lowermost second semiconductor chip 400, may be substantially aligned with portions of the outer border of the planar shape of the composite spacer 100A. For example, side surfaces of the lowermost first semiconductor chip 300, except for the side surface of the lowermost first semiconductor chip 300 that faces the lowermost second semiconductor chip 400, may be substantially aligned with side surfaces of the composite spacer 100A. In FIG. 5, the outer border of the planar shape of the lowermost first semiconductor chip 300 is indicated by a dashed line.

A portion of the outer border of the planar shape of the lowermost second semiconductor chip 400 from among the plurality of second semiconductor chips 400 may be substantially aligned with a portion of the outer border of the planar shape of the composite spacer 100A. For example, as shown in FIG. 5, portions of the outer border of the planar shape of the lowermost second semiconductor chip 400 except for a portion of the outer border of the planar shape of the lowermost second semiconductor chip 400, which faces the lowermost first semiconductor chip 300, may be substantially aligned with portions of the outer border of the planar shape of the composite spacer 100A. For example, side surfaces of the lowermost second semiconductor chip 400, except for the side surface of the lowermost second semiconductor chip 400 that faces the lowermost first semiconductor chip 300, may be substantially aligned with side surfaces of the composite spacer 100A. In FIG. 5, the outer border of the planar shape of the lowermost second semiconductor chip 400 is indicated by a dashed line.

The respective outer borders of the plurality of first semiconductor chips 300 may be substantially aligned with each other in the vertical direction. Each of the plurality of first semiconductor chips 300 may have a face-up arrangement such that an active surface of the first semiconductor substrate 310 faces upwards. Likewise, the respective outer borders of the plurality of second semiconductor chips 400 may be substantially aligned with each other in the vertical direction. Each of the plurality of second semiconductor chips 400 may have a face-up arrangement such that an active surface of the second semiconductor substrate 410 faces upwards.

Unlike the semiconductor package 1A according to an embodiment of the present inventive concept, in general semiconductor packages, a spacer and a controller chip may be arranged between stacked semiconductor chips and a base substrate.

In the semiconductor package 1A according to an embodiment of the present inventive concept, the composite spacer 100A that includes the first device region 120A, which functions as a controller chip, is arranged under the plurality of first semiconductor chips 300 that are stacked on each other and under the plurality of second semiconductor chips 400 that are stacked on each other. By doing this, unlike the general case of separately arranging a spacer and a controller chip, because the composite spacer 100A, in which a spacer and a controller are integrated, is fabricated, the productivity of the semiconductor package 1A may increase. In addition, because the integrated composite spacer 100A is fabricated by using a silicon substrate, the stiffness of the semiconductor package 1A may increase unlike a general semiconductor package in which a spacer and a controller are separately arranged. Furthermore, because the integrated composite spacer 100A may reduce or prevent the warpage of the semiconductor package 1A during the fabrication and operation of the semiconductor package 1A, the composite spacer 100A may increase the mechanical properties of the semiconductor package 1A.

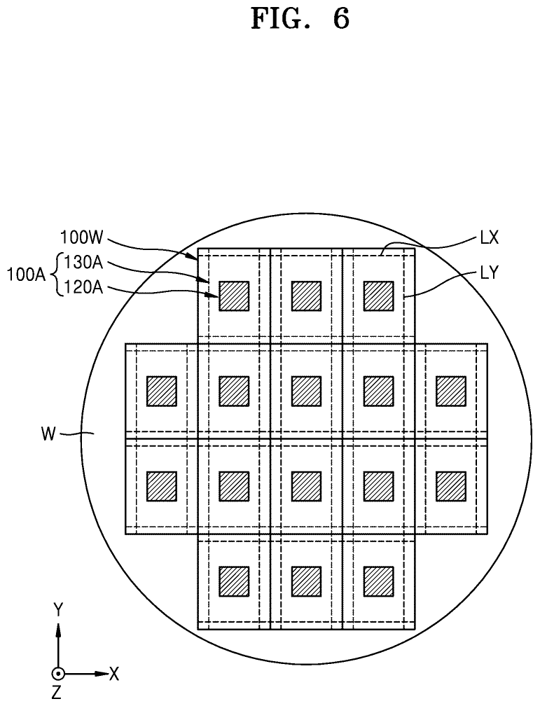

FIG. 6 is a plan view illustrating a method of fabricating the composite spacer 100A that is included in the semiconductor package 1A, according to an embodiment of the present inventive concept.

Referring to FIG. 6, a preliminary composite spacer 100W including the first device region 120A may be formed in a plural number on a wafer W. The preliminary composite spacer 100W formed in the same manner as in FIG. 3 may be cut along a first line LX and a second line LY, which are respectively different from the first line LX and the second line LY in FIG. 3, thereby forming the composite spacer 100A. For example, the size and shape of the composite spacer 100A may be determined depending on positions at which the first line LX and the second line LY are set. The composite spacers 100 and 100A having different sizes and shapes may be fabricated from the same wafer W depending on cutting lines.

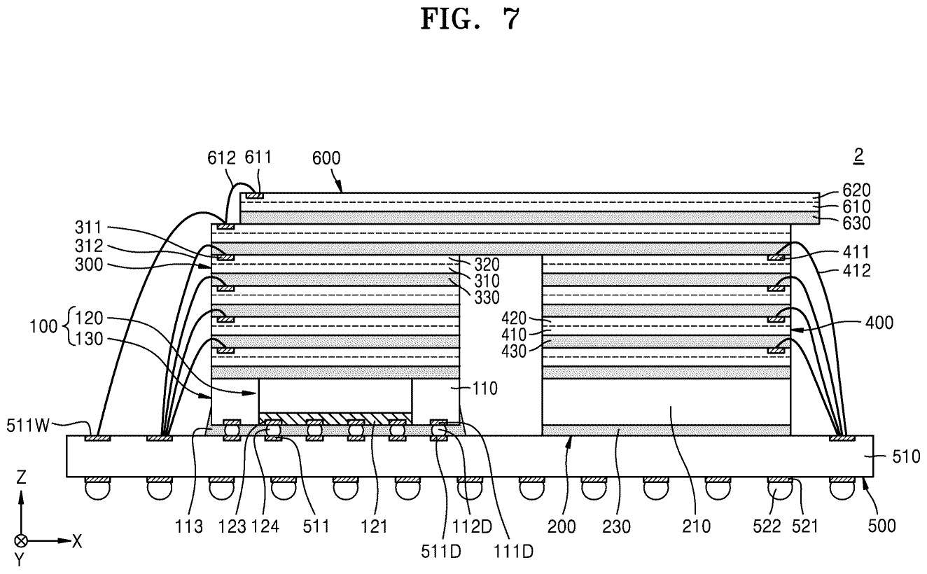

FIG. 7 is a cross-sectional view of a semiconductor package 2 according to an embodiment of the present inventive concept.

Referring to FIG. 7, the semiconductor package 2 according to an embodiment of the present inventive concept may include a base substrate 510, a composite spacer 100, a first spacer 200, a plurality of first semiconductor chips 300 that are stacked on each other, a plurality of second semiconductor chips 400 that are stacked on each other, and a third semiconductor chip 600.

The third semiconductor chip 600 may be arranged on the plurality of first semiconductor chips 300 that are stacked on each other and the plurality of second semiconductor chips 400 that are stacked on each other. Each third semiconductor chip 600 may include a third semiconductor substrate 610 having an active surface on which a third semiconductor device 620 is formed, and a plurality of third chip pads 611 arranged on the upper surface of the third semiconductor chip 600.

One end of each of the plurality of third bonding wires 612 may be attached to each of the third chip pads 611 of the third semiconductor chip 600, and the other end of each of the plurality of third bonding wires 612 may be attached to each of a plurality of base bonding pads 511W. When a plurality of third semiconductor chips 600 are stacked, a third bonding wire 612 may be provided for the connection of each of the third chip pads 611, which are respectively included in different third semiconductor chips 600.

The third semiconductor chip 600 may have a third die-attach film 630 that is attached to the lower surface thereof and may be attached onto a structure placed under the die-attach film 630. For example, the third die-attach film 630 may be arranged between the third semiconductor substrate 610 and each of the uppermost first semiconductor chip 300 from among the plurality of first semiconductor chips 300 and the uppermost second semiconductor chip 400 from among the plurality of second semiconductor chips 400.

Each third semiconductor chip 600 may include a third semiconductor device 620. The third semiconductor device 620 may include, for example, a memory device. For example, the third semiconductor device 620 may include DRAM or flash memory. A plurality of third semiconductor chips 600 may be stacked on each other. For example, two third semiconductor chips 600 may be stacked as shown in FIG. 7. However, the present inventive concept is not limited thereto. For example, there may be four, six, eight, or the like third semiconductor chips 600 that are stacked on each other.

The third bonding wire 612 extending from the third chip pad 611 of the third semiconductor chip 600 may be connected to, for example, each of the base bonding pads 511W that are adjacent to the plurality of first semiconductor chips 300. In such a case, to reduce an electrical connection distance between the plurality of first semiconductor chips 300 and the third semiconductor chip 600, the composite spacer 100 may be arranged under the plurality of first semiconductor chips 300 rather than under the plurality of second semiconductor chips 400.

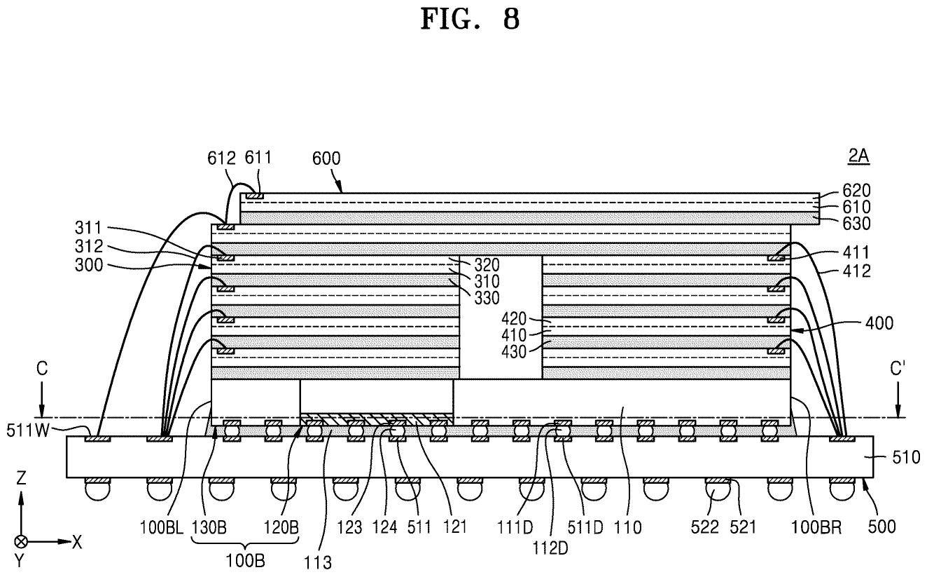

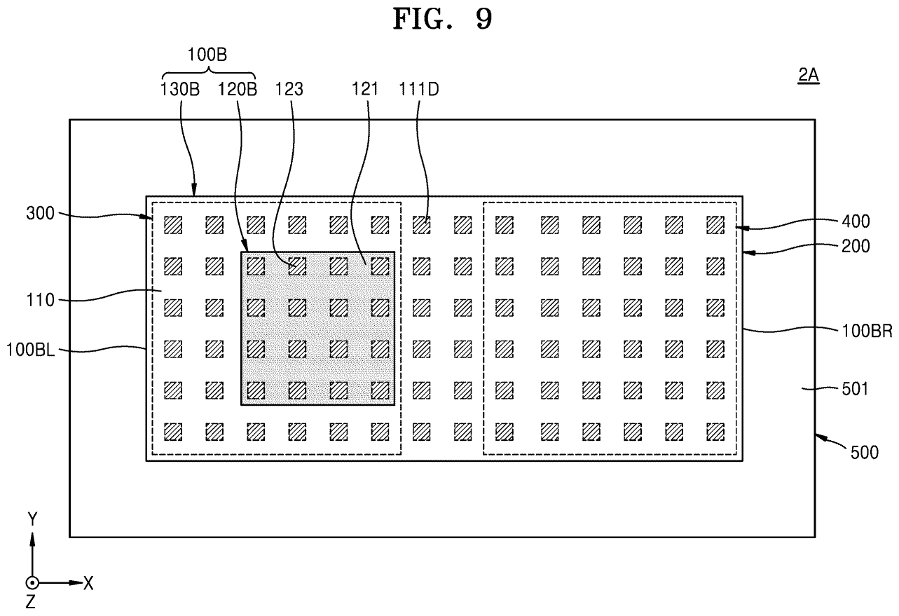

FIG. 8 is a cross-sectional view of a semiconductor package 2A according to an embodiment of the present inventive concept. FIG. 9 is a cross-sectional view of the semiconductor package 2A, taken along the line C-C′ of FIG. 8.

Referring to FIGS. 8 and 9, the semiconductor package 2A according to an embodiment of the present inventive concept may include a base substrate 510, a composite spacer 100B, a plurality of first semiconductor chips 300 that are stacked on each other, a plurality of second semiconductor chips 400 that are stacked on each other, and a third semiconductor chip 600. The plurality of first semiconductor chips 300 may be sequentially stacked and arranged on the composite spacer 100B, and the plurality of second semiconductor chips 400 may also be sequentially stacked and arranged on the composite spacer 100B. The third semiconductor chip 600 may be arranged on the plurality of first semiconductor chips 300 that are stacked on each other and the plurality of second semiconductor chips 400 that are stacked on each other.

The composite spacer 100B may be arranged on the base substrate 510. The composite spacer 100B may include a first device region 120B. A remaining region except for the first device region 120B in the composite spacer 100B may be referred to as a buffer region 130B.

The third bonding wire 612 extending from the third chip pad 611 of the third semiconductor chip 600 may be connected to, for example, each of the base bonding pads 511W that are adjacent to the plurality of first semiconductor chips 300. In such a case, to reduce an electrical connection distance between the plurality of first semiconductor chips 300 and the third semiconductor chip 600, the first device region 120B may be arranged in the composite spacer 100B such that the first device region 120B is closer to the plurality of first semiconductor chips 300 than to the plurality of second semiconductor chips 400, instead of arranging the first device region 120B in a central portion of the composite spacer 100B.

For example, the first device region 120B may be arranged closer to a first side surface 100BL of the composite spacer 100B than to a second side surface 100BR of the composite spacer 100B. A side surface of the composite spacer 100B, which is close to the base bonding pads 511W that are connected to the third semiconductor chip 600 via the plurality of third bonding wires 612, may be referred to as the first side surface 100BL, and a side surface of the composite spacer 100B, which is opposite to the first side surface 100BL, from among the side surfaces of the composite spacer 100B may be referred to as the second side surface 100BR.

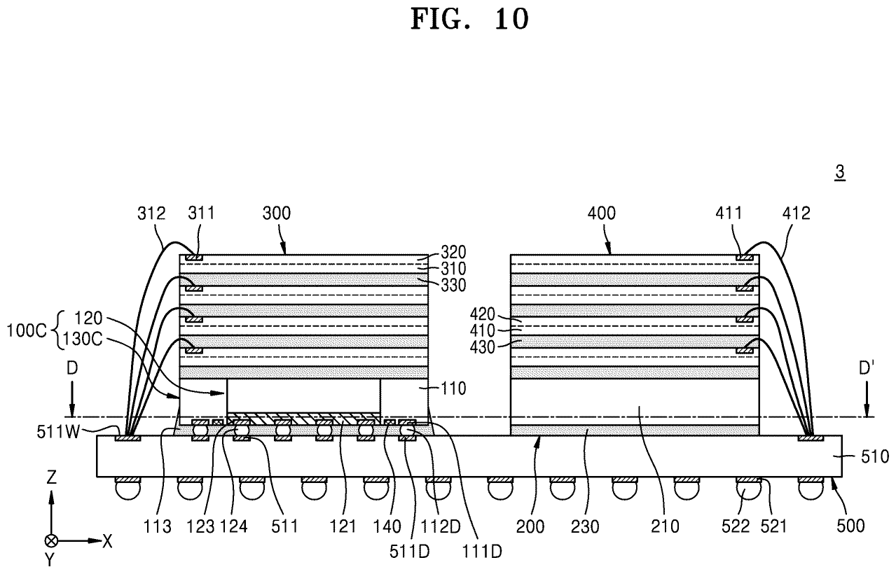

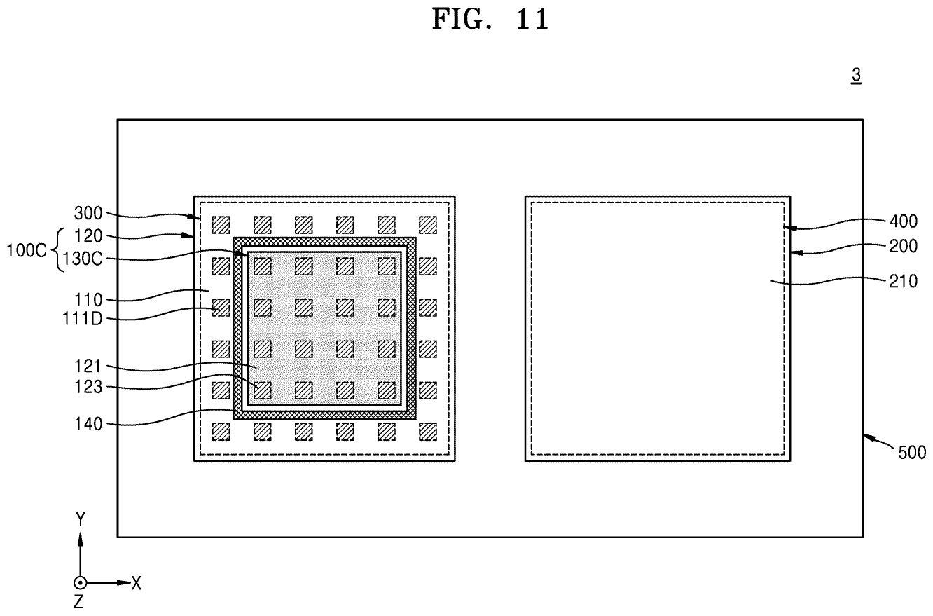

FIG. 10 is a cross-sectional view of a semiconductor package 3 according to an embodiment of the present inventive concept. FIG. 11 is a cross-sectional view of the semiconductor package 3, taken along the line D-D′ of FIG. 10.

Referring to FIGS. 10 and 11, the semiconductor package 3 according to an embodiment of the present inventive concept may include a base substrate 510, a composite spacer 100C, a first spacer 200, a plurality of first semiconductor chips 300 that are stacked on each other, and a plurality of second semiconductor chips 400 that are stacked on each other. The composite spacer 100C may include a first device region 120, a buffer region 130C, and a guard ring 140.

The guard ring 140 may be laterally apart from the first device region 120 and be arranged in the buffer region 130C. As shown in FIG. 11, the guard ring 140 may be arranged spaced apart from the outer border of the first device region 120 and may at least partially surround the first device region 120. The guard ring 140 may prevent a crack, which permeates the inside from the edge of the composite spacer 100C, from reaching the first device region 120 in a cutting process for fabricating the composite spacer 100C and may protect the first device region 120 from static electricity and noise.

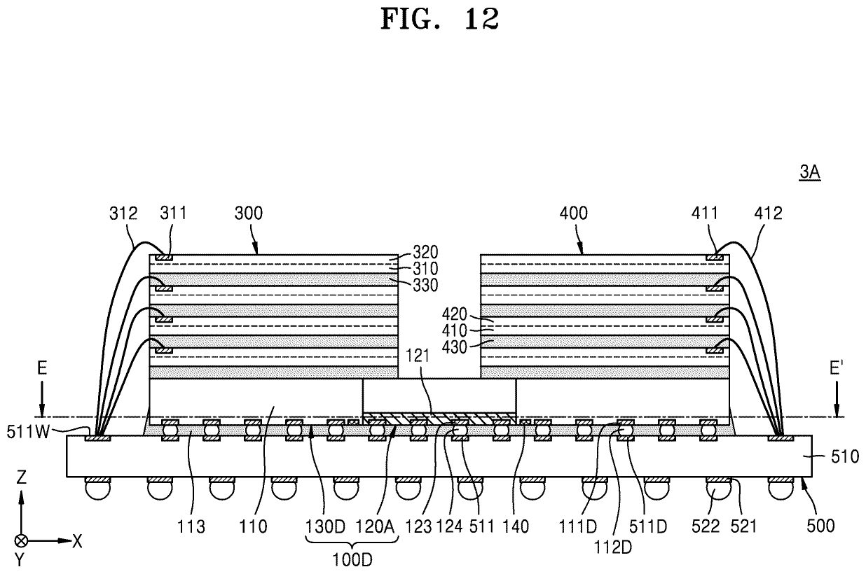

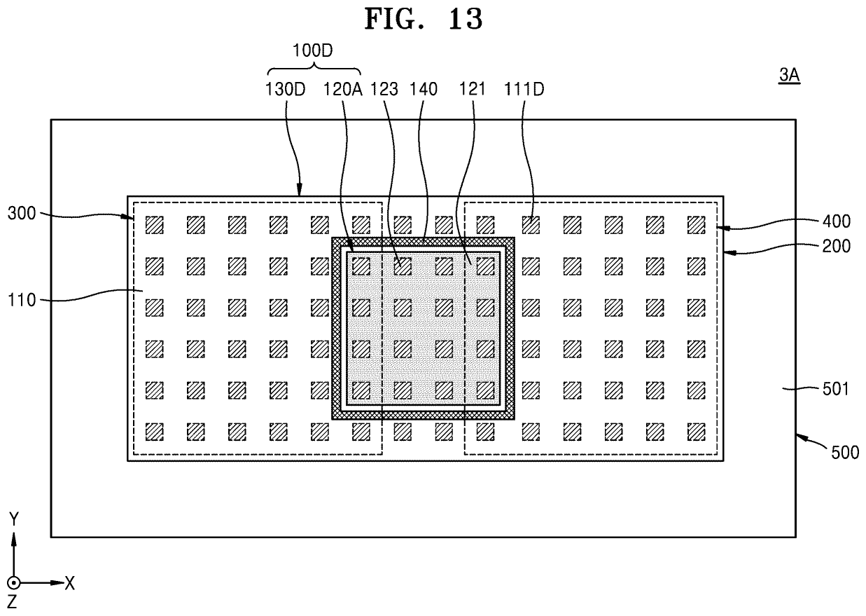

FIG. 12 is a cross-sectional view of a semiconductor package 3A according to an embodiment of the present inventive concept. FIG. 13 is a cross-sectional view of the semiconductor package 3A, taken along the line E-E′ of FIG. 12.

Referring to FIGS. 12 and 13, the semiconductor package 3A according to an embodiment may include a base substrate 510, a composite spacer 100D, a plurality of first semiconductor chips 300 that are stacked on each other, and a plurality of second semiconductor chips 400 that are stacked on each other. The composite spacer 100D may include a first device region 120A, a buffer region 130D, and a guard ring 140.

The guard ring 140 may be laterally spaced apart from the first device region 120A and be arranged in the buffer region 130D. As shown in FIG. 13, the guard ring 140 may be arranged spaced apart from the outer border of the first device region 120A and may at least partially surround the first device region 120A. The guard ring 140 may prevent a crack, which permeates the inside from the edge of the composite spacer 100D, from reaching the first device region 120A in a cutting process for fabricating the composite spacer 100D and may protect the first device region 120A from static electricity and noise.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a base substrate;
a first spacer disposed on the base substrate;
a composite spacer disposed on the base substrate and laterally spaced apart from the first spacer;
a plurality of first semiconductor chips stacked on the composite spacer; and
a plurality of second semiconductor chips stacked on the first spacer,
wherein a portion of the composite spacer comprises a first device region,
wherein a remaining portion of the composite spacer comprises a buffer region,
wherein the first device region comprises a semiconductor device,
wherein the buffer region does not comprise a semiconductor device, and
the first spacer does not comprise a semiconductor device.

2. The semiconductor package of claim 1, wherein the buffer region surrounds side portions of the first device region.

3. The semiconductor package of claim 2, further comprising connection terminals and dummy terminals, which are disposed between the composite spacer and the base substrate,
wherein the connection terminals are arranged on the first device region and electrically connect the first device region to the base substrate, and
the dummy terminals are arranged on the buffer region.

4. The semiconductor package of claim 3, wherein a planar shape of the composite spacer is substantially the same as a planar shape of a lowermost first semiconductor chip from among the plurality of first semiconductor chips, and
an outer border of the lowermost first semiconductor chip is substantially aligned with an outer border of the composite spacer.

5. The semiconductor package of claim 4, wherein the composite spacer comprises a guard ring, and
the guard ring is laterally spaced apart from the first device region and is arranged on one surface of the composite spacer that comprises the first device region.

6. The semiconductor package of claim 4, wherein a planar shape of the first spacer is substantially the same as a planar shape of a lowermost second semiconductor chip from among the plurality of second semiconductor chips,
wherein an outer border of the lowermost second semiconductor chip is substantially aligned with an outer border of the first spacer, and
a thickness of the first spacer is substantially equal to a thickness of the composite spacer.

7. The semiconductor package of claim 6, wherein the plurality of first semiconductor chips have same planar shapes as one another,
wherein respective outer borders of the plurality of first semiconductor chips are substantially aligned with each other,
wherein the plurality of second semiconductor chips have same planar shapes as each other, and
respective outer borders of the plurality of second semiconductor chips are substantially aligned with each other.

8. The semiconductor package of claim 7, wherein an adhesive film is arranged between the first spacer and the base substrate.

9. The semiconductor package of claim 6, further comprising a third semiconductor chip arranged on the plurality of first semiconductor chips and the plurality of second semiconductor chips.

10. The semiconductor package of claim 9, wherein third bonding pads, which are disposed on an upper surface of the third semiconductor chip, are respectively and electrically connected to base bonding pads, which are disposed on the base substrate, via bonding wires, and
the base bonding pads are adjacent to an outer border of the base substrate and adjacent to a side surface of the composite spacer.

11. The semiconductor package of claim 7, wherein an outer border of the first device region is spaced apart from the outer border of the composite spacer by about 50 um or more.

12. A semiconductor package comprising:
a base substrate;
a composite spacer disposed on the base substrate;
a plurality of first semiconductor chips stacked on the composite spacer; and
a plurality of second semiconductor chips stacked on the composite spacer and laterally spaced apart from the plurality of first semiconductor chips,
wherein a portion of the composite spacer comprises a first device region,
wherein a remaining portion of the composite spacer comprises a buffer region,
wherein the first device region comprises a semiconductor device, and
the buffer region does not comprise a semiconductor device.

13. The semiconductor package of claim 12, further comprising connection terminals and dummy terminals, which are disposed between the composite spacer and the base substrate,
wherein the connection terminals are arranged on the first device region and electrically connect the first device region to the base substrate,
wherein the dummy terminals are arranged on the buffer region and do not electrically connect the buffer region to the base substrate, and
the buffer region at least partially surrounds the first device region.

14. The semiconductor package of claim 13, wherein a first portion of an outer border of the composite spacer is substantially aligned with a portion of an outer border of a lowermost first semiconductor chip except for a portion of the outer border of the lowermost first semiconductor chip, which faces the plurality of second semiconductor chips,
wherein a second portion of the outer border of the composite spacer is substantially aligned with a portion of an outer border of a lowermost second semiconductor chip except for a portion of the outer border of the lowermost second semiconductor chip, which faces the plurality of first semiconductor chips,
wherein the lowermost first semiconductor chip is closest to the base substrate, from among the plurality of first semiconductor chips, and
the lowermost second semiconductor chip is closest to the base substrate, from among the plurality of second semiconductor chips.

15. The semiconductor package of claim 14, wherein the composite spacer comprises a guard ring, and
the guard ring is laterally spaced apart from the first device region and is arranged in the composite spacer.

16. The semiconductor package of claim 15, wherein the plurality of first semiconductor chips have same planar shapes as one another,
wherein respective outer borders of the plurality of first semiconductor chips are substantially aligned with each other,
wherein the plurality of second semiconductor chips have same planar shapes as one another, and
respective outer borders of the plurality of second semiconductor chips are substantially aligned with each other.

17. The semiconductor package of claim 16, further comprising a third semiconductor chip arranged on the plurality of first semiconductor chips and the plurality of second semiconductor chips.

18. The semiconductor package of claim 17, wherein third bonding pads, which are disposed on an upper surface of the third semiconductor chip, are respectively and electrically connected to base bonding pads, which are disposed on the base substrate, via bonding wires, and
the first device region is arranged closer to a first side surface from among side surfaces of the composite spacer than to a second side surface from among the side surfaces of the composite spacer, wherein the first side surface is closer to the base bonding pads than the second side surface.

19. A semiconductor package comprising:
a base substrate;
a first spacer disposed on the base substrate;
a composite spacer disposed on the base substrate and laterally spaced apart from the first spacer;
a plurality of first semiconductor chips stacked on the composite spacer;
a plurality of second semiconductor chips stacked on the first spacer;
connection terminals and dummy terminals, which are disposed between the composite spacer and the base substrate; and
a plurality of third semiconductor chips stacked on the plurality of first semiconductor chips and the plurality of second semiconductor chips,
wherein a portion of the composite spacer comprises a first device region,
wherein a remaining portion of the composite spacer comprises a buffer region,
wherein the first device region comprises a semiconductor device,
wherein the buffer region does not comprise a semiconductor device,
wherein the first spacer does not comprise a semiconductor device,
wherein the buffer region at least partially surrounds the first device region,
wherein the connection terminals are arranged on the first device region and electrically connect the first device region to the base substrate,
wherein the dummy terminals are arranged on the buffer region,
wherein a planar shape of the composite spacer is substantially same as a planar shape of a lowermost first semiconductor chip from among the plurality of first semiconductor chips,
wherein an outer border of the lowermost first semiconductor chip is substantially aligned with an outer border of the composite spacer,
wherein a planar shape of the first spacer is substantially same as a planar shape of a lowermost second semiconductor chip from among the plurality of second semiconductor chips,
wherein an outer border of the lowermost second semiconductor chip is substantially aligned with an outer border of the first spacer,
wherein the plurality of first semiconductor chips have same planar shapes as one another,
wherein respective outer borders of the plurality of first semiconductor chips are substantially aligned with each other,
wherein the plurality of second semiconductor chips have same planar shapes as one another, and
respective outer borders of the plurality of second semiconductor chips are substantially aligned with each other.

20. The semiconductor package of claim 19, wherein third bonding pads, which are disposed on an upper surface of each of the plurality of third semiconductor chips, are respectively and electrically connected to base bonding pads, which are disposed on the base substrate, via bonding wires,
wherein the base bonding pads are adjacent to an outer border of the base substrate and are closer to the composite spacer than to the first spacer, and
a thickness of the first spacer is substantially equal to a thickness of the composite spacer.
